(19) United States
(12) Patent Application Publication
(10) Pub. No.: US 2008/0123696 A1
(43) Pub. Date: May 29, 2008

(54) Semiconductor laser device having scattering portion and method of fabricating the device

(75) Inventors: Han-youl Ryu, Suwon-si (KR); Join-in Shim, Seoul (KR); Youn-joon Sung, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/898,577

(22) Filed: Sep. 13, 2007

(30) Foreign Application Priority Data
Nov. 28, 2006 (KR) 10-2006-0118565

(51) Int. Cl. H01S 3/10; H01L 21/00

(52) U.S. Cl. 372/9; 438/29; 257/E21.001

(57) ABSTRACT

Provided is a semiconductor laser device comprising a substrate, a light emitting structure including a first clad layer, an active layer, and a second clad layer sequentially stacked on the substrate, and a scattering portion formed on the bottom surface of the substrate in order to scatter light. As such, the semiconductor laser device may emit higher quality laser light.

### PRIORITY STATEMENT

This application claims priority under 35 U.S.C. to Korean Patent Application No. 2006-0118565, filed on Nov. 28, 2006, in the Korean Intellectual Property Office (KIPO), the entire contents of which are herein incorporated by reference.

### BACKGROUND

1. Field

Example embodiments relate to a semiconductor laser device which reduces the ripples of emitted light, and a method of fabricating the semiconductor laser device.

2. Description of Related Art

Semiconductor laser devices that mainly emit blue and purple light may be fabricated using semiconductor material. These semiconductor laser devices can emit laser light having a wavelength within the range of 360 nm to 490 nm (e.g., ultraviolet to blue green). Currently, blue and purple laser light having a wavelength within the range of 400 nm to 450 nm is being used in various technological fields. A semiconductor laser device having an excitation wavelength of about 405 nm can be used as a light source of next generation large capacity optical storage media (e.g., Blu-ray disks or high definition (HD) digital versatile disks (DVDs)). In addition, a semiconductor laser device having a blue excitation wavelength of about 450 nm can be used as a blue light source in a laser display system. A semiconductor laser device producing a wavelength of 500 nm or more can be used as a green light source in a laser display system. In addition, the blue and purple semiconductor laser device can possibly be used as a light source of a high definition laser printer. A semiconductor laser device emitting laser light of a shorter wavelength of 400 nm or less can be fabricated using a nitride-based semiconductor material and can be used in biological research and within certain medical fields.

In a nitride semiconductor laser device, if the composition of Al in the n-clad layer formed of AlGaN is not large enough, or if the n-clad layer is not thick enough, optical confinement is degraded and the light leaks under the n-clad layer.

In a nitride semiconductor laser device using a sapphire substrate, the light leaks under the n-clad layer to the n-contact layer between the sapphire substrate and the n-clad layer. Some of the light exits via the cross section of the substrate located on the side of the light exiting face, and some of the light exits via the cross section of the n-contact layer located on the side of the light exiting face. In a nitride semiconductor layer device grown on a GaN substrate, the light leaks under the n-clad layer to the substrate. Some of the light exits via a light exiting face of the substrate. The leaking light interferes with a far-field pattern of the light emitted from the semiconductor laser device, thereby causing ripples as illustrated in FIGS. 1A and 1B.

The ripples of the far field pattern can cause problems in applying the blue and purple semiconductor laser device to a system. For example, if the semiconductor laser device is used as a blue light source in a laser display system, the ripples may cause the displayed images to be inconsistent, thereby degrading image quality. If the semiconductor laser device is used as the light source of an optical storage medium, noise may increase and an error may occur when a signal is being read while reproducing information, and thus, the reliability of the optical pickup is degraded.

In order to reduce the ripple in the far field pattern, the light leaking under the n-clad layer must be blocked. To accomplish this, the composition of Al in the n-clad layer must be increased or the thickness of the n-clad layer must be increased in order to strengthen the optical confinement. However, if the composition of the Al in the n-clad layer is too high or if the n-clad layer is too thick, cracks are likely to form during the growing process of the semiconductor laser device, and thus, blocking leaking light may be limited using this method. When the wavelength of the light becomes longer, leaking light increases and thus, it may not be feasible to apply the semiconductor laser device as a light source of a laser display.

A technology of blocking leaking light from the substrate by depositing an optical shielding layer at a cross-section of the substrate located at the side of the light exiting face in a nitride semiconductor laser device has been disclosed. The semiconductor laser device is attached to a jig that covers a region of the light exiting face, on which the optical shielding layer is not formed, and the optical shielding layer is deposited at the cross section of the substrate.

However, the region of the light exiting face on which the optical shielding layer is not formed is just a few μm thick and thus, it may be difficult to fabricate a jig that can't cover the region. If the jig covers the cross section of the substrate at the light exiting face side, the optical shielding layer is not formed sufficiently and the light leakage cannot be sufficiently blocked. In addition, when the semiconductor laser device is attached to the jig, it may be difficult to maintain accuracy. Therefore, the light exiting face can be damaged when attached to the jig, thereby degrading light emission performance.

A semiconductor laser device providing a light absorption layer between a substrate and a clad layer has also been disclosed. Because the absorption layer must absorb light, it has a narrower band gap than the active layer. The absorption layer having the afore-mentioned function must have a large composition of In in the nitride semiconductor laser device using InₓGa₁₋ₓN. However, it is not easy to grow such a material.

### SUMMARY

Example embodiments provide a semiconductor laser device that may reduce the ripples of emitted light, and a method of fabricating the semiconductor laser device.

According to example embodiments, a semiconductor laser device may include a substrate, a light emitting structure including a first clad layer, an active layer, a second clad layer sequentially stacked on the substrate, and a scattering portion formed on the bottom surface of the substrate in order to scatter light.

The semiconductor laser device may further include a n-electrode disposed on the bottom surface of the substrate, and the n-electrode may be disposed on the area outside of the scattering portion.

The semiconductor laser device may further include a ridge wave guide formed by protruding a part of the second clad layer upward, and the scattering portion may be wider than the ridge wave guide.

The semiconductor laser device may also include a n-electrode disposed on the upper surface of the substrate, and the scattering portion may be formed on the entire bottom surface of the substrate.

The substrate may be a GaN substrate or a SiC substrate.

According to example embodiments, a method of fabricating a semiconductor laser device may include forming a light emitting structure by stacking material layers including a first clad layer, an active layer, and a second clad layer on a substrate, and forming a scattering portion having a rough surface by wet-etching the bottom surface of the substrate.

In forming the scattering portion, a KOH solution may be used as an etchant.

The forming of the light emitting structure may include forming a ridge wave guide by etching a portion of the second clad layer. In the forming of the scattering portion, a portion of the bottom surface of the substrate, which corresponds to the width of the ridge wave guide, may be wet-etched.

### BRIEF DESCRIPTION OF THE DRAWINGS

Example embodiments will be more clearly understood from the following detailed description taken in conjunction with the accompanying drawings. FIGS. 1A-7B represent non-limiting, example embodiments as described herein.

FIG. 1A is a graph illustrating ripples in a far field pattern of a nitride semiconductor laser device adopting a sapphire substrate according to the conventional art;

FIG. 1B is a graph illustrating ripples in a far field pattern of a nitride semiconductor laser device adopting a GaN substrate according to the conventional art;

FIG. 2 is a perspective view of a semiconductor laser device according to example embodiments;

FIG. 3 is a perspective view of a semiconductor laser device according to example embodiments;

FIG. 4 is a diagram illustrating paths of light leaking from the light emission structure to the substrate of the semiconductor laser device according to example embodiments;

FIG. 5 is a graph illustrating the ratio of light incident to the bottom surface of the substrate versus the light leaking toward the substrate;

FIG. 6 is a diagram illustrating the angle range of the light affecting the ripples in the substrate; and

FIGS. 7A and 7B are graphs illustrating far field patterns in which a scattering portion is not formed and in which the ripples are reduced by the scattering portion in the semiconductor laser device, respectively.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout; As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments: only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

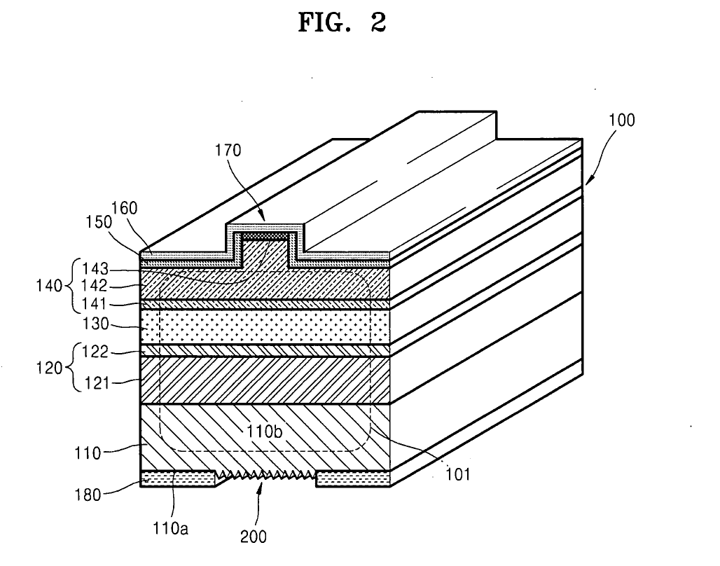

FIG. 2 is a perspective view of a semiconductor laser device according to example embodiments. FIG. 2 exaggerates the semiconductor laser device to some degree in order to clarify features of example embodiments. The semiconductor laser device of example embodiments may be a GaN-based Group III-V nitride semiconductor laser device.

Referring to FIG. 2, the semiconductor laser device may include a substrate 110 and a light emission structure 100 including a first material layer 120, an active layer 130, and a second material layer 140 sequentially stacked on the substrate 110. Example embodiments feature a scattering portion 200 that will be described later and thus, the scope of example embodiments may not be limited to the light emission structure 100 of FIG. 2.

The substrate 110 may be a Group III-V nitride semiconductor substrate (e.g., GaN or SiC).

The first material layer 120 may include a first clad layer 121 and a first waveguide layer 122. The first clad layer 121 may be a n-AlGaN/GaN layer, for example. The first waveguide layer 122 may be a GaN-based Group III-V nitride semiconductor layer, for example, a n-GaN layer. The first waveguide layer 122 may have a refractive index lower than the refractive index of the active layer 130 and higher than the refractive index of the first clad layer 121.

The active layer 130 may be a material layer emitting light by the coupling of carriers (e.g., electrons and holes) and may be a GaN-based Group III-V nitride semiconductor layer having a multi-quantum well (MQW) structure. The active layer 130 may be a material layer formed by adding Indium (In) to the GaN based Group III-V nitride semiconductor layer (e.g., an InGaN layer) at a desired, or alternatively, a predetermined ratio.

The second material layer 140 may include a second clad layer 142, a cap layer 143, and a second wave guide layer 141. The second clad layer 142 may be the same material as the first clad layer 121 with the exception that the p-type material may be doped. A portion of the second clad layer 142 may protrude upward to form a ridge wave guide 170. The second wave guide layer 141 may be a GaN based Group III-V nitride semiconductor layer (e.g., a p-GaN layer). The second wave guide layer 141 may have a refractive index lower than the refractive index of the active layer 130 and higher than the refractive index of the second clad layer 142.

The composition of the first clad layer 121, the active layer 130, and the second clad layer 142 may be represented as AₓGa₁₋ₓn_{y}N_{1-y}(0≦x≦0.3, 0≦y≦0.3).

The cap layer 143 may be a GaN-based Group III-V nitride semiconductor layer and may be a direct transition type semiconductor layer doped with p-type conductive impurities (e.g., a p-GaN layer). Otherwise, the cap layer 143 may be a GaN layer, an AlGaN layer, or an InGaN layer including Al or In.

A p-type electrode layer 160 may be electrically connected to the cap layer 143, and a current restriction layer 150 may provide for the p-type electrode layer 160 limitedly contacting the cap layer 143.

Well-known methods may be used to fabricate the above light emitting structure 100. For example, the GaN compound layer may be stacked on the substrate 110 by a metal organic chemical vapor deposition (MOCVD) or an epitaxial growth method to form the first clad layer 121, the first wave guide layer 122, the active layer 130, the second wave guide layer 141, and the second clad layer 142. Then, the second clad layer 142 may be etched to form the ridge wave guide 170 protruding upward to supply electric current to the restricted area of the second clad layer 142. The second clad layer 142 and the cap layer 143 may be etched together after forming the cap layer 143 on the second clad layer 142 to form the ridge wave guide 170.

A scattering portion 200 may be formed on the bottom surface 110a of the substrate 110. The scattering portion 200 may scatter light and may be formed by wet-etching the bottom surface 110a of the substrate 110. A KOH solution may be used as the etchant. According to experimental research, when the bottom surface 110a of the substrate 110 is wet-etched for about 20 minutes at a temperature of about 90° C., a surface roughness having a depth of about 500 nm may be formed. The scope of example embodiments may not be limited by these etching conditions, and any type of wet-etching may be performed as long as the wet-etching method is capable of producing a rough surface that scatters light on the bottom surface 110a of the substrate 110. In addition, example embodiments may not be limited to the above degree of surface roughness.

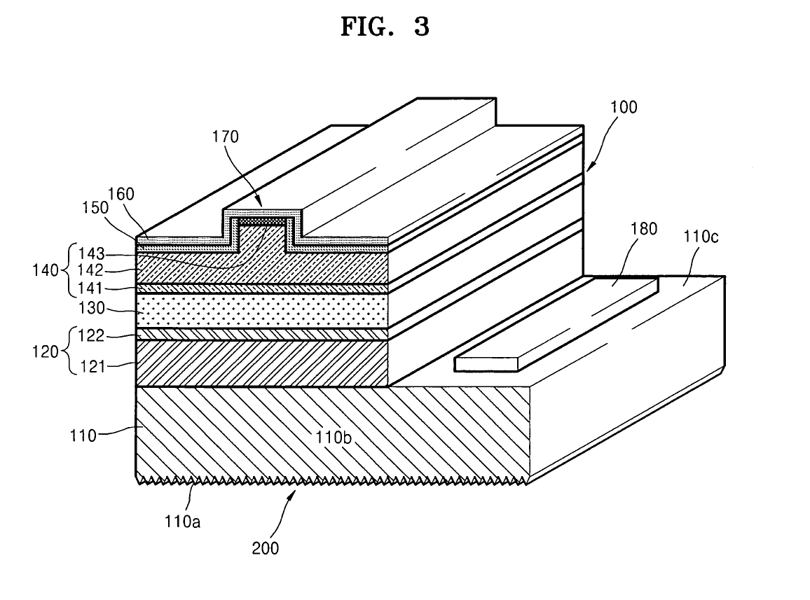

Because light may be primarily generated on a portion of the light emitting face 101, which corresponds to the width of the ridge wave guide 170, the scattering portion 200 may have the same or a greater width than the ridge wave guide 170. In the semiconductor laser device having a vertical structure as illustrated in FIG. 2, in which a n-electrode 180 is formed on the bottom surface 110a of the substrate 110, the n-electrode 180 may be located on areas other than the scattering portion 200. As such, in order to form the scattering portion 200, the portion of the bottom surface 110a of the substrate 110 on which the n-electrode 180 will be formed may be masked and then, the wet-etching may be performed. Alternatively, the portion on which the scattering portion 200 will be formed may be masked, the n-electrode 180 may be deposited, and then the masking may be removed and the wet-etching performed to form the scattering portion 200. In addition, as illustrated in FIG. 3, in the semiconductor laser device having a horizontal structure, in which the n-electrode 180 is formed on the upper surface 110c of the substrate 110, the scattering portion 200 may be formed on the entire bottom surface 110a of the substrate 110.

The operation and effects of the semiconductor laser device according to example embodiments will now be described as follows.

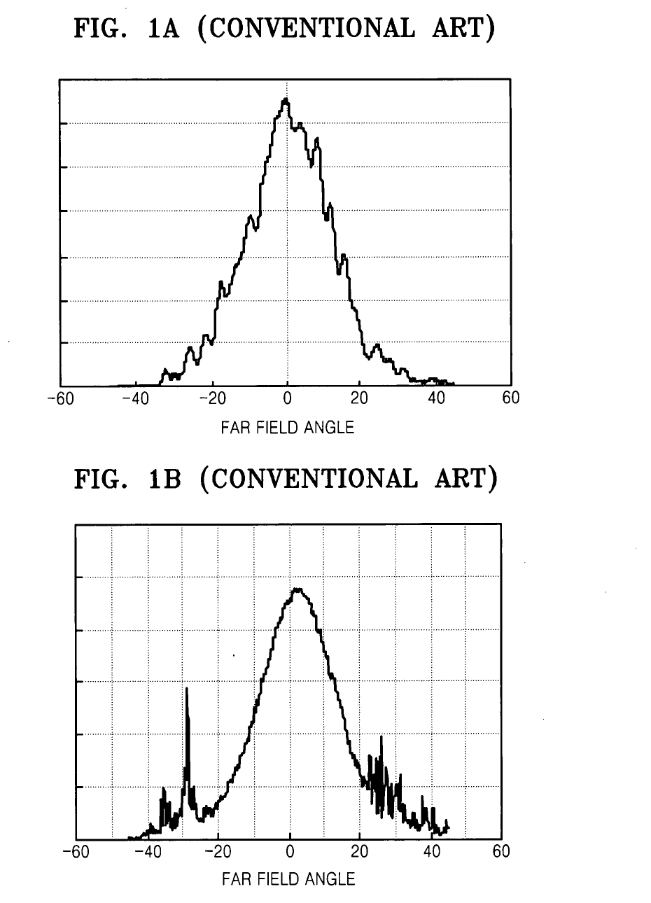

When electric current is supplied to the first and second material layers 120 and 140 through the p-electrode 160 and the n-electrode 180, light may be emitted from the active layer 130 due to recombination of the carriers (e.g., electrons and holes). The first and second wave guide layers 122 and 141, located on the upper and lower portions of the active layer 130, may amplify the light emitted from the active layer 130. The amplified light may be discharged through the light emitting face 101 of the light emitting structure 100. Some of the light generated in the active layer 130 may exit to the substrate 110 through the first clad layer 121. If the leaking light exits through an end portion 110b of the substrate 110, the leaking light may interfere with a far-field pattern of the light emitted from the light emitting face 101; and thus ripples may be formed as illustrated in FIGS. 1A and 1B.

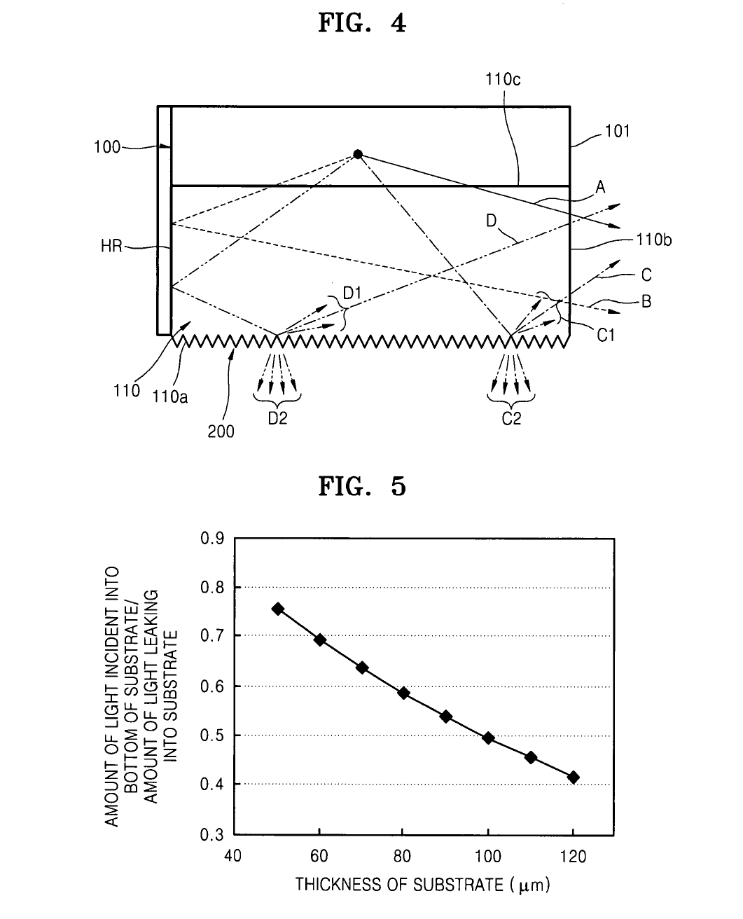

In order to reduce the ripples, the scattering portion 200 may be formed on the bottom surface 110a of the substrate 110 for randomly scattering light leaking toward the substrate 110. Referring to FIG. 4, the light generated in the light emitting structure 100 may exit towards the light emitting face 101 through four paths. Light A leaks from the light emitting structure 100 toward the substrate 110 and exits through the end portion 110b of the substrate 110. Light B leaks from the light emitting structure 100 to the substrate 110, is reflected by a high reflection coating (HR), and then exits through the light emitting face 101. Light C leaks from the light emitting structure 100 to the substrate 110, is reflected by the bottom surface 110a of the substrate, and then exits through the end portion 110b of the substrate 110. Light D leaks from the light emitting structure 100 to the substrate 110, is reflected by the high reflection coating HR, and then exits through the end portion 110b of the substrate 110.

Light A and light B may not be reflected by the bottom surface 110a of the substrate 110, but may exit directly through the end portion 110b of the substrate 110. Light C and light D may be reflected once or more than once by the bottom surface 110a of the substrate 110, and then may exit through the end portion 110b of the substrate 110. If light reflected by the bottom surface 110a of the substrate 110, for example, light C and light D, can be reduced, light exiting through the end portion 110b of the substrate 110 may be reduced, and thus the ripples may be reduced.

The amount of light reflected by the bottom surface 110a of the substrate 110 and exiting the end portion 110b of the substrate 110 may be calculated as follows. FIG. 5 is a graph illustrating the ratio between light incident into the bottom surface 110a of the substrate and light leaking toward the substrate 110 with respect to the thickness of the substrate 110. In this case, the angle of light exiting through the end portion 110b of the substrate 110 should be considered.

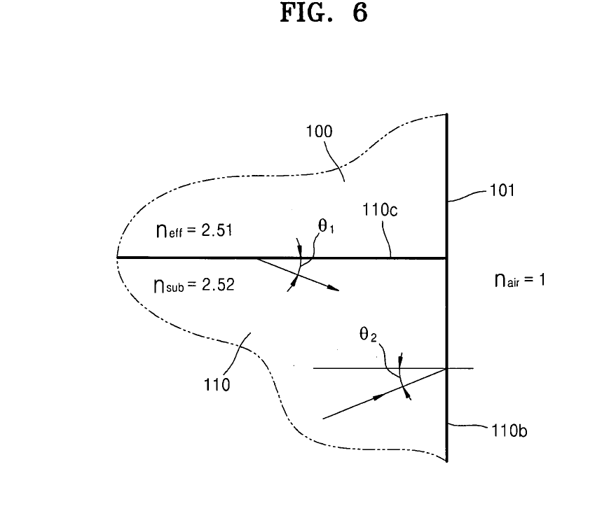

Referring to FIG. 6, when light leaks from the light emitting structure 100 to the substrate 110, the minimum angle (θᵢ) between the light and the upper surface 110c of the substrate 110 may be about 5°. When the effective refractive index (n_{eff}) of the laser mode in the light emitting structure 100 is about 2.51 and the refractive index (n_{sub}) of the GaN substrate 110 is about 2.52, the angle θ₁ may be calculated as cos⁻¹(n_{eff}/n_{sub}). When light exits through the end portion 110b from the inside of the substrate 110, the maximum angle (θ₂) between the light and the horizontal surface (e.g., the upper surface 110c of the substrate 110) may be about 23° in the case of total reflection. When it is assumed that the refractive index of air (nₐᵢᵣ) is about 1, the angle θ₂ may be calculated as sin⁻¹(nₐᵢᵣ/n_{sub}). The light leaking into the substrate 110 and affecting the ripples in the far-field pattern may have an angle within the range of about 5° to 23° with respect to the upper surface 110c of the substrate 110. The above angle range may correspond to a range of about 13° to 90° at the outside of the substrate 110. No ripple may occur at an angle of 13° or smaller, and the calculation result coincides with most measurements. Therefore, when the above calculation is performed, light within the angle range of about 5° to 23° in the substrate 110 may be considered. A cavity length may be assumed to be about 650 μm.

Referring to FIG. 5, when the thickness of the substrate 110 is about 100 μg/m or less, the percentage of light incident to the bottom surface 110a of the substrate 110 before exiting through the end portion 110b of the substrate 110 may be about 50% or greater. Light within the angle range of about 5° to 23° may all exit through the end portion 110b of the substrate 110. Even if light within the range of about 5° to 23° is incident to the bottom surface 110a of the substrate 110, the light may totally be reflected. Thus, light within the range of about 5° to 23° may exit through the end portion 110b of the substrate 110, and then may affect the ripples. Therefore, if the reflection rate of light on the bottom surface 110a of the substrate 110 is reduced, the amount of light affecting the ripples may be reduced. According to the calculation result, when the cavity length is about 650 μm and the thickness of the substrate 110 is about 100 μm, if the reflection rate of the bottom surface 110a of the substrate 110 is reduced to 0, the ripples may be halved.

In order to reduce the reflection rate of the bottom surface 110a of the substrate 110, the semiconductor laser device of example embodiments may adopt the scattering portion 200. The scattering portion 200 may form a rough surface on the bottom surface 110a of the substrate 110 as described above in order to diffusely reflect and scatter light. Light C and light D incident to the bottom surface 110a of the substrate 110 may be diffusely reflected by the scattering portion 200. Lights C1 and D1 satisfying the total reflection condition on the bottom surface 110a of the substrate 110 among diffusely reflected light may be re-reflected into the substrate 110. However, other lights C2 and D2 may exit through the bottom surface 110a of the substrate 110. Among lights C1 and D1, the light within the range of about 5° to 23° may exit through the end portion 110b of the substrate 110, and the other light may be re-reflected into the substrate 110 and scattered on the bottom surface 110a of the substrate 110. Light within the range of about 5° to 23° that affects the ripples may be greatly reduced by repeating the above processes.

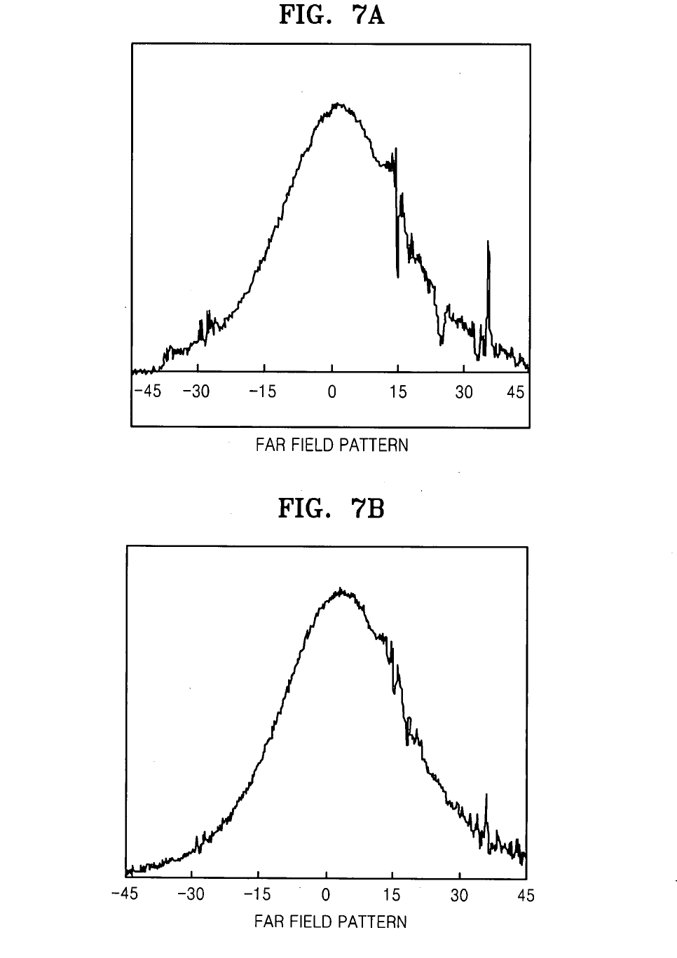

FIGS. 7A and 7B are graphs illustrating far-field patterns before and after forming the scattering portion 200 in the semiconductor laser device. Referring to FIG. 7A, before the scattering portion 200 is formed, the amount of the ripples may be about 26%. However, referring to FIG. 7B, the amount of the ripples may be about 11%, which is much less than the amount of ripples of FIG. 7A.

According to the semiconductor laser device according to example embodiments, a scattering portion may be formed on the bottom surface of the substrate and thus, the ripples in the far-field pattern of the laser emitted from the light emitting structure may be reduced effectively to realize a semiconductor laser diode emitting higher quality laser light.

According to the method of fabricating the semiconductor laser device according to example embodiments, a scattering portion may be formed on the bottom surface of the substrate without affecting the light emitting structure and other components using a wet-etching process. Therefore, a reliable semiconductor laser device emitting higher quality laser light may be fabricated.

The foregoing is illustrative of example embodiments and is not to be construed as limiting thereof. Although example embodiments have been described; those skilled in the art will readily appreciate that many modifications are possible in example embodiments without materially departing from the novel teachings and advantages of example embodiments. Accordingly, all such modifications are intended to be included within the scope of the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A semiconductor laser device comprising:
a substrate;
a light emitting structure including a first clad layer, an active layer, and a second clad layer sequentially stacked on the substrate; and
a scattering portion on a bottom surface of the substrate in order to scatter light.

2. The semiconductor laser device of claim 1, further comprising:
a n-electrode on the bottom surface of the substrate, wherein the n-electrode is disposed on an area outside of the scattering portion.

3. The semiconductor laser device of claim 2, further comprising:
a ridge wave guide formed by protruding a portion of the second clad layer upward, wherein the scattering portion is wider than the ridge wave guide.

4. The semiconductor laser device of claim 1, further comprising:
a n-electrode on an upper surface of the substrate, wherein the scattering portion is formed on the entire bottom surface of the substrate.

5. The semiconductor laser device of claim 1, wherein the substrate is a GaN substrate or a SiC substrate.

6. A method of fabricating a semiconductor laser device, the method comprising:
forming a light emitting structure by stacking material layers including a first clad layer, an active layer, and a second clad layer on a substrate; and
forming a scattering portion having a rough surface by wet-etching a bottom surface of the substrate.

7. The method of claim 6, wherein in the forming of the scattering portion, a KOH solution is used as an etchant.

8. The method of claim 6, wherein the forming of the light emitting structure comprises:
forming a ridge wave guide by etching a portion of the second clad layer, wherein in the forming of the scattering portion, a portion of the bottom surface of the substrate corresponding to the width of the ridge wave guide is wet-etched.

9. The method of claim 6, wherein the substrate is a GaN substrate or a SiC substrate.
